(19) United States
(12) Patent Application Publication
(10) Pub. No.: US 2014/0367643 A1
(43) Pub. Date: Dec. 18, 2014

(54) ORGANIC LIGHT EMITTING DISPLAY AND MANUFACTURING METHOD THEREOF

(71) Applicant: Samsung Display Co., Ltd., Yongin-City (KR)

(72) Inventor: Seung-Uk NOH, Yongin-City (KR)

(73) Assignee: Samsung Display Co., Ltd., Yongin-City (KR)

(21) Appl. No.: 14/027,630

(22) Filed: Sep. 16, 2013

(30) Foreign Application Priority Data
Jun. 14, 2013 (KR) 10-2013-0068097

(51) Int. Cl. H01L 27/32

(52) U.S. Cl. CPC H01L 27/3258
USPC 257/40; 438/34

(57) ABSTRACT

An organic light emitting display includes a substrate, a first electrode, a first insulating layer, a second insulating layer, an organic layer and a second electrode. The first electrode is on the substrate. The first insulating layer is on the substrate including the first electrode, and an opening is defined in the first insulating layer to expose the first electrode. The second insulating layer is on the first insulating layer, where a width of the first insulating layer is larger than that of the first insulating layer. The organic layer is on the first electrode in the opening. The second electrode is on the organic layer and the second insulating layer.

This application claims priority to Korean Patent Application No. 10-2013-0068097, filed on Jun. 14, 2013, and all the benefits accruing therefrom under 35 U.S.C. §119, the entire contents of which are incorporated herein by reference in their entirety.

### BACKGROUND

1. Field

The invention relates to an organic light emitting display using a liquid material in a method of manufacturing thereof, and a manufacturing method thereof.

2. Description of the Related Art

An organic light emitting display is divided into a passive matrix organic light emitting display and an active matrix organic light emitting display. In the passive matrix organic light emitting display, organic light emitting diodes are connected in a matrix form to scan lines and data lines, thereby constituting a pixel array. In the active matrix organic light emitting display, the operation of each pixel is controlled by a thin film transistor which serves as a switch. Generally, the active matrix organic light emitting display includes thin film transistors configured to transmit signals and capacitors configured to maintain the signals.

An organic light emitting diode includes an anode electrode, an organic layer and a cathode electrode. The organic layer includes a hole transport layer, an emissive layer and an electron transport layer. If a voltage is applied between the anode and cathode electrodes, holes injected into the anode electrode and electrons injected into the cathode electrode are recombined in the emissive layer, thereby generating excitons. The generated excitons are changed from an excited state to a ground state, thereby emitting light.

### SUMMARY

One or more exemplary embodiment provides an organic light emitting display and a manufacturing method thereof, which reduce or effectively prevent physical and/or electrical contact of an organic layer with another layer, due to an increase in thickness of the organic layer during a drying process.

According to an exemplary embodiment of the invention, there is provided an organic light emitting display, including: a substrate; a first electrode on the substrate; a first insulating layer on the first electrode, an opening defined in the first insulating layer and exposing the first electrode; a second insulating layer on the first insulating layer, where a width of the first insulating layer is larger than that of the first insulating layer; an organic layer on the first electrode in the opening; and a second electrode on the organic layer and the second insulating layer.

A thickness of the organic layer at an edge portion of the opening may be larger than that of the organic layer at a central portion of the opening. The organic layer may contact the second insulating layer at the edge portion of the opening.

The organic layer may include a hole injection layer, an emissive layer and an electron injection layer. The organic layer may further include a hole transport layer and an electron transport layer.

A width of a lower portion of the second insulating layer may be larger than that of an upper portion of the second insulating layer. The second insulating layer may have a curved surface.

The organic light emitting display may further include a device forming layer on the substrate. The device forming layer may include a thin film transistor coupled to the first electrode; and a third insulating layer between the thin film transistor and the first electrode.

According to another exemplary embodiment of the invention, there is provided a method of manufacturing an organic light emitting display, the method including: forming a first electrode on a substrate; forming a first insulating layer on the substrate including the first electrode; patterning the first insulating layer, thereby forming an opening in the first insulating layer to expose the first electrode in an emission region; forming an organic layer on the first electrode in the opening; forming a second insulating layer on the first insulating layer to have a width wider than that of the first insulating layer; and forming a second electrode on the organic layer and the second insulating layer.

The forming the organic layer may include coating a liquid material on the first electrode in the opening; and drying the coated liquid material.

In the drying the coated liquid material, a thickness of the organic layer at an edge portion of the opening may be larger than that of the organic layer at a central portion of the opening. The organic layer may contact the second insulating layer at the edge portion of the opening.

The forming the organic layer may include forming a hole injection layer by coating a hole injection layer liquid material on the first electrode in the opening and drying the coated hole injection layer liquid material; forming an emissive layer by coating an emissive layer liquid material on the hole injection layer and drying the coated emissive layer liquid material; and forming an electron injection layer by coating an electron injection layer liquid material on the emissive layer and drying the coated electron injection layer liquid material.

The forming the second insulating layer may include forming a second insulating material layer on the first insulating layer and the organic layer; and patterning the second insulating material layer. In the patterning the second insulating material layer, the width of a lower portion of the second insulating layer may be formed larger than that of an upper portion of the second insulating layer.

The forming the second insulating layer may include coating a second insulating layer liquid material on the first insulating layer; and drying the coated second insulating layer liquid material.

The method may further include forming a thin film transistor on the substrate; forming a third insulating layer on the substrate including the thin film transistor; and forming, in the third insulating layer, a via hole through which the thin film transistor and the first electrode are coupled to each other.

### BRIEF DESCRIPTION OF THE DRAWINGS

The above and other features of this disclosure will become more apparent by describing in further detail exemplary embodiments thereof with reference to the accompanying drawings in which:.

FIG. 1 is a cross-sectional view illustrating an exemplary embodiment of an organic light emitting display according to the invention.

FIG. 2 is a plan view illustrating the organic light emitting display of FIG. 1.

FIGS. 3A and 3B are cross-sectional views of modified exemplary embodiments of the organic light emitting display, taken along line I1-I2 of FIG. 2, respectively.

FIG. 4 is a cross-sectional view illustrating another exemplary embodiment of an organic light emitting display according to the invention.

FIGS. 5A to 5G are cross-sectional views illustrating an exemplary embodiment of a method of manufacturing an organic light emitting display according to the invention.

FIG. 6 is a cross-sectional view illustrating still another exemplary embodiment of an organic light emitting display according to the invention.

### DETAILED DESCRIPTION

In the following detailed description, only certain exemplary embodiments of the invention have been shown and described, simply by way of illustration. As those skilled in the art would realize, the described embodiments may be modified in various different ways, all without departing from the spirit or scope of the invention. Accordingly, the drawings and description are to be regarded as illustrative in nature and not restrictive. In the drawing figures, dimensions may be exaggerated for clarity of illustration.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art

In addition, when an element is referred to as being “on” another element, it can be directly on the another element or be indirectly on the another element with one or more intervening elements interposed therebetween. It will be understood that when an element is referred to as being “between” two elements, it can be the only element between the two elements, or one or more intervening elements may also be present. Also, when an element is referred to as being “connected to” another element, it can be directly connected to the another element or be indirectly connected to the another element with one or more intervening elements interposed therebetween. Hereinafter, like reference numerals refer to like elements. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “below,” “lower,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “lower” relative to other elements or features would then be oriented “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

An organic light emitting diode includes an anode electrode, an organic layer and a cathode electrode. The organic layer of the organic light emitting diode includes an organic material. Since the organic material constituting the organic layer is relatively easily dissolved in a solvent, a method has been introduced for forming an organic layer by coating a liquid material through a spin coating, ink jet, nozzle or slit process.

Since processes for patterning the organic layer, such as exposure, development and etching are not included in the method, it is possible to reduce processing time and cost. Further, it is possible to selectively form the organic layer even on a relatively large-area substrate, and to reduce the amount of material used for the organic layer.

Generally, in a case where a liquid material is used for the organic layer, the thickness of a predetermined portion of the organic layer may be larger than that of another portion due to a difference in vapor density during a process of drying the liquid material. Therefore, there remains a need for an improved organic light emitting display and a method of manufacturing thereof.

Hereinafter, the invention will be described in detail with reference to the accompanying drawings.

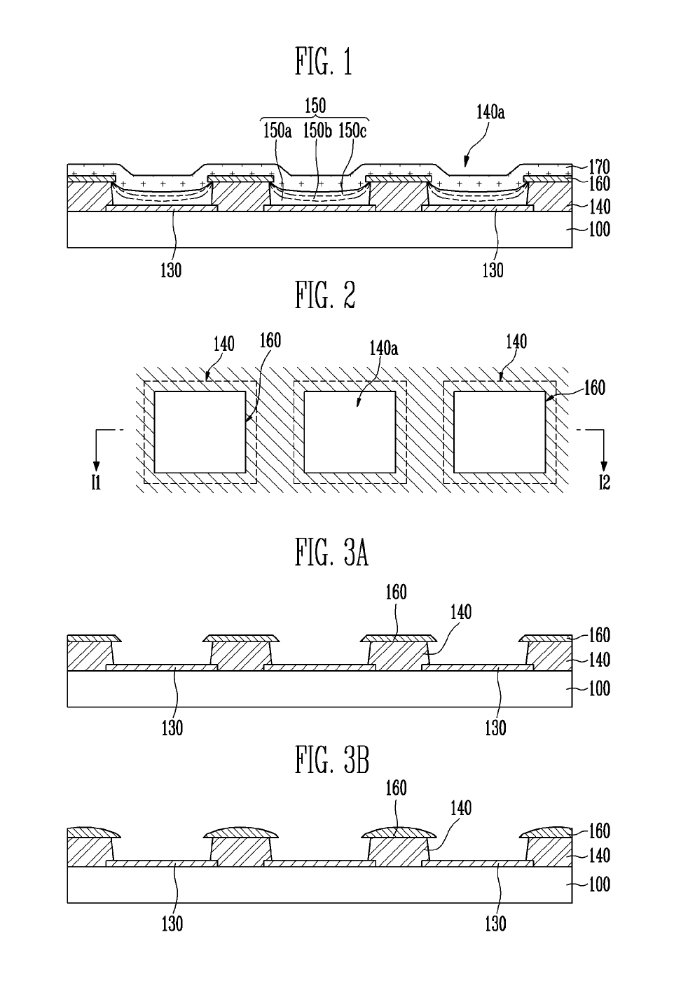

FIG. 1 is a cross-sectional view illustrating an exemplary embodiment of an organic light emitting display according to the invention.

The organic light emitting display includes a pixel array configured to display an image. Each pixel of the pixel array includes an organic light emitting diode configured to emit at least one of red, green, blue and white lights. The organic light emitting diode includes a first electrode, an organic emissive layer and a second electrode. The organic emissive layer includes a hole injection layer, an emissive layer and an electron injection layer.

Referring to FIG. 1, a plurality of organic light emitting diodes is disposed on a substrate 100. Each of the plurality of organic light emitting diodes includes a first electrode 130, an organic layer 150 and a second electrode 170.

The first electrodes 130 of the plurality of organic light emitting diodes are disposed on the substrate 100, and a first insulating layer 140 is disposed on the substrate 100 including the first electrodes 130. An opening 140a is defined in the first insulating layer 140 so that each first electrode 130 in an emission region is exposed.

A second insulating layer 160 is disposed on the first insulating layer 140, and the organic layer 150 is disposed on the first electrode 130. In a direction parallel to the substrate 100, widths of portions of the second insulating layer 160 overlapping portions of the first insulating layer 140, are larger than those of the portions of the first insulating layer 140. As shown in FIG. 1, the portions of the second insulating layer 160 protrude further toward the electrodes 130 at the emission regions than the portions of the first insulating layer 140.

The second electrode 170 is disposed on the organic layer 150 and the second insulating layer 160. The second electrode 170 may include discrete portions respectively corresponding to portions of the organic layer 150, but the invention is not limited thereto. The second electrode 170 may be common to plurality of organic light emitting diodes, and may be a single, unitary, indivisible member, but the invention is not limited thereto.

The substrate 100 includes an insulative material such as glass, quartz, ceramic or plastic.

In the organic light emitting diode, the first electrode 130 is an anode electrode, and may include a transparent conductive material such as indium tin oxide (“ITO”) or indium zinc oxide (“IZO”), or opaque metal.

The first insulating layer 140 is a pixel defining layer which defines pixels in the organic light emitting display and allows the pixels to be electrically insulated from one another. The first insulating layer 140 may include an organic material such as acryl resin or polyimide resin, or inorganic material such as silicon oxide (SiO₂), titanium oxide (TiO₂) or silicon nitride (SiNₓ).

The organic layer 150 may include, for example, a hole injection layer 150a, an emissive layer 150b and an electron injection layer 150c. In an alternative exemplary embodiment, the organic layer 150 may further include a hole transport layer (not shown) and an electron transport layer (not shown). The emissive layer 150b may include a material for emitting red, green, blue and/or white light.

A cross-section thickness of the organic layer 150 at an edge portion of the opening 140a is larger than that at a central portion of the opening 140a. The cross-sectional thickness is taken from a common plane or surface, such as from an upper surface of the first electrode 130. At least one layer, e.g., the hole injection layer 150a, the emissive layer 150b or the electron injection layer 150c, at the edge portion of the opening 140a may be contacted with a lower surface of the second insulating layer 160. As illustrated in FIG. 1, the at least one layer of the organic layer 150 contacts a lower surface of the portion of the second insulating layer 160 which protrudes further toward the electrodes 130 at the emission regions than the portions of the first insulating layer 140.

The second insulating layer 160 is a barrier layer which reduces or effectively prevents contact between the organic layer 150 and the second electrode 170. As shown in FIG. 2, the second insulating layer 160 is wider than the first insulating layer 140 in a plan view, so that opposing side portions of the second insulating layer 160 may be positioned in and/or overlapping the opening 140a defined in the first insulating layer 140.

The second insulating layer 160 may include an organic or inorganic material, and may be the same material used as the first insulating layer 140. Where the opposing side portions of the second insulating layer 160 are positioned in the opening 140a, the second insulating layer 160 may include a transparent material.

As illustrated in FIG. 1, widths of upper and lower portions of the second insulating layer 160, taken parallel to the substrate 100, are substantially the same, but the invention is not limited thereto.

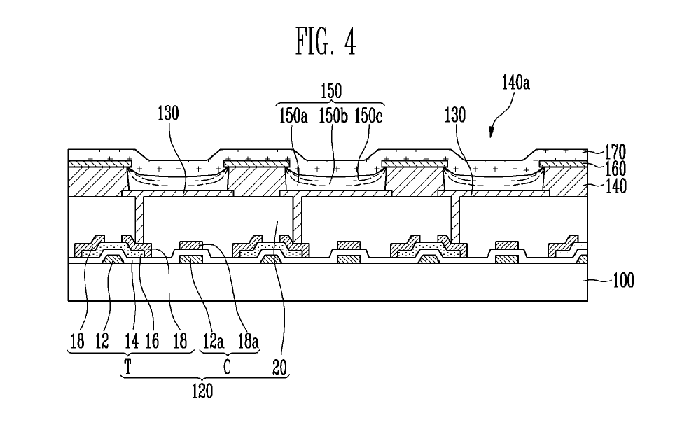

FIGS. 3A and 3B are cross-sectional views of modified exemplary embodiments of the organic light emitting display, taken along line I1-I2 of FIG. 2, respectively. The organic layer 150 and the second electrode 170 are omitted for convenience of illustration.

A width of a lower portion of the second insulating layer 160 may be larger than that of an upper portion of the second insulating layer 160 as shown in a modified exemplary embodiment of FIG. 3A, such that an edge side surface is inclined. In another modified exemplary embodiment, the second insulating layer 160 may have a curved surface as shown in FIG. 3B. Where the second insulating layer 160 is disposed as described above, a step difference in the surface of the second insulating layer 160 is minimized, so that it is possible to prevent disconnection caused by step coverage when the second electrode 170 is formed in a method of manufacturing the organic light emitting display.

In the organic light emitting diode, the second electrode 170 is a cathode electrode, and may be a common electrode disposed above the substrate 100 including the plurality of first electrodes 130. The second electrode 170 may include a metal material such as aluminum (Al) or silver (Ag).

FIG. 4 is a cross-sectional view illustrating another exemplary embodiment of an organic light emitting display according to the invention.

Referring to FIG. 4, a device forming layer 120 is disposed on a substrate 100. The device forming layer 120 may include a thin film transistor T configured to transmit a signal to an organic light emitting diode, a capacitor C configured to maintain the signal, and an insulating layer 20 disposed on the thin film transistor T and the capacitor C.

The thin film transistor T includes a gate electrode 12 disposed on the substrate 100, a semiconductor layer 16 disposed above the gate electrode 12 and electrically insulated from the gate electrode 12 by an insulating layer 14, and source and drain electrodes 18 respectively connected source and drain regions of the semiconductor layer 16.

The capacitor C is disposed on the substrate 100 adjacent to the thin film transistor T. The capacitor C may be a stacked structure including a lower electrode 12a, the insulating layer 14 and an upper electrode 18a. The lower electrode 12a may be in a same layer as the gate electrode 12, and the lower electrode 18a may be in a same layer as the source and drain electrodes 18, but the invention is not limited thereto.

A first electrode 130 of the organic light emitting diode is disposed on the device forming layer 120 configured as described above so as to be connected to the source or drain electrode 18 of the thin film transistor T. A via hole is defined in the insulating layer 20, between the thin film transistor T and the first electrode 130, and exposes the source or drain electrode 18 of the thin film transistor T. The first electrode 130 is connected to the source or drain electrode 18 of the thin film transistor T through the via hole in the insulating layer 20 between the thin film transistor T and the first electrode 130.

Hereinafter, an exemplary embodiment of the invention will be described in detail through a manufacturing method of an organic light emitting display.

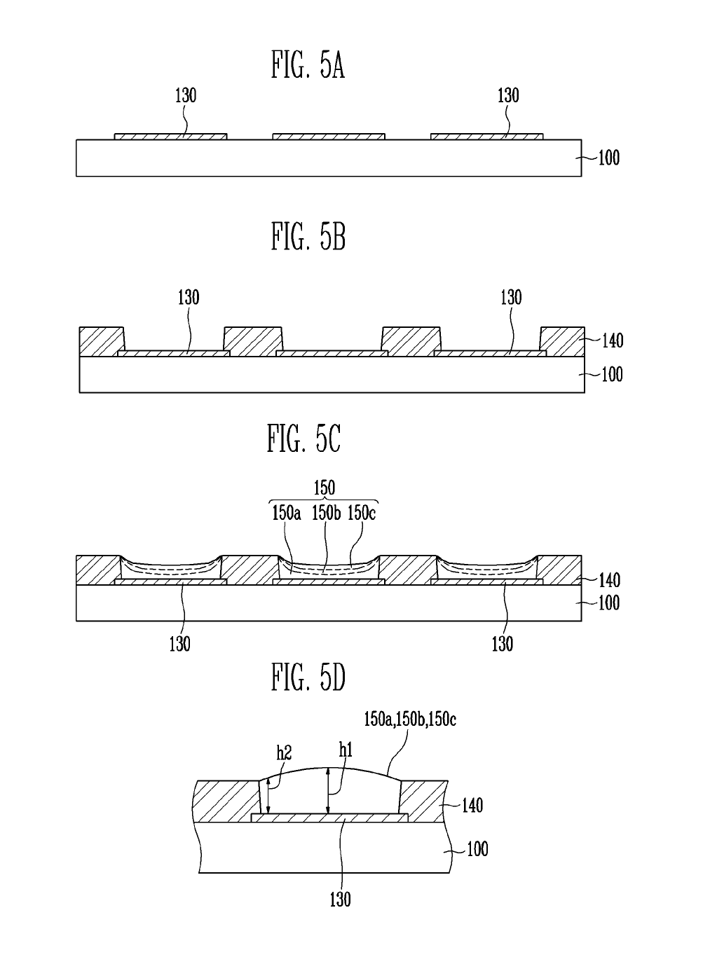

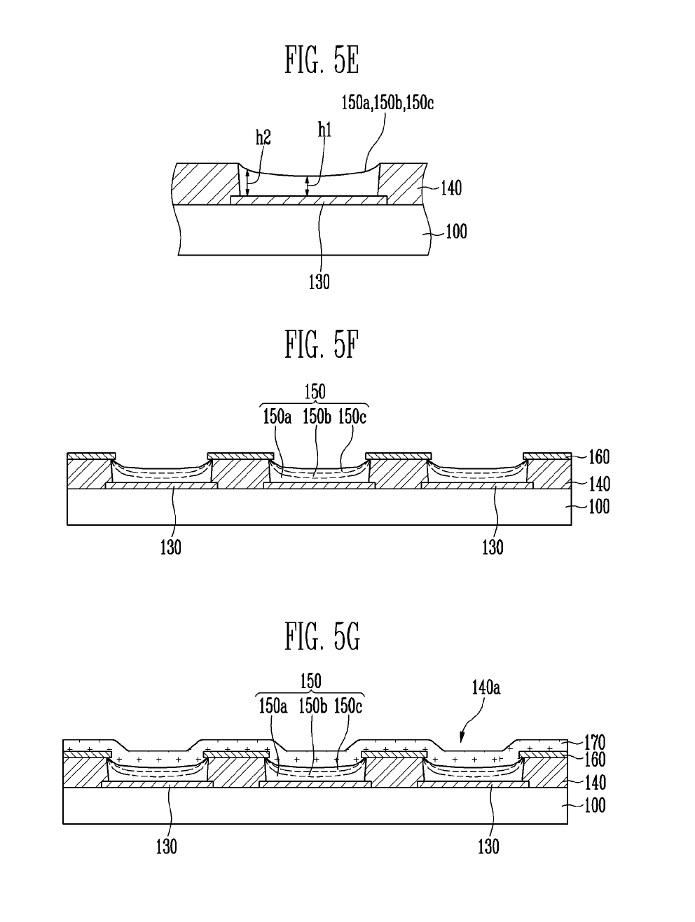

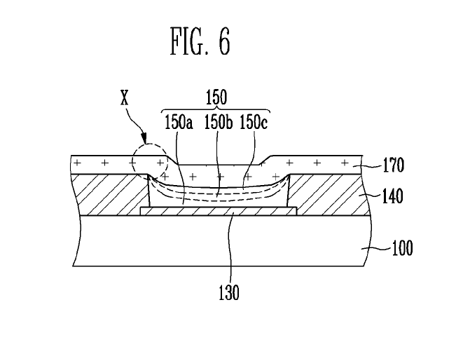

FIGS. 5A to 5G are cross-sectional views illustrating an exemplary embodiment of a manufacturing method of an organic light emitting display according to the invention.

Referring to FIG. 5A, a plurality of first electrodes 130 is formed (e.g., provided) on a substrate 100.

The substrate 100 includes an insulating substrate such as glass, quartz, ceramic, plastic, etc. The first electrodes 130 may be formed of a transparent conductive material such as ITO or IZO, or an opaque metal material.

Referring to FIG. 5B, a first insulating material layer is formed on the substrate 100 including the plurality of first electrode 130 and then patterned, thereby forming an opening 140a in a first insulating layer 140 so that each first electrode 130 in an emission region is exposed.

The first insulating layer 140 may be formed of an organic material such as acryl resin, polyimide resin, polyvinyl pyrolidone (“PVP”) or polystyrene (“PS”), or in organic material such as SiO₂, TiO₂ or SiNₓ.

Referring to FIG. 5C, an organic layer 150 is formed on the first electrode 130 and in the opening 140a which exposes the first electrode 130. The organic layer 150 includes, for example, a hole injection layer 150a, an emissive layer 150b and an electron injection layer 150c. The organic layer 150 may further include a hole transport layer (not shown) and an electron transport layer (not shown).

Each of the hole injection layer 150a, the emissive layer 150b and the electron injection layer 150c may be formed using a liquid material. The liquid material is a solution in which an organic material for forming each of the hole injection layer 150a, the emissive layer 150b and the electron injection layer 150c is mixed in a solvent. Each of the hole injection layer 150a, the emissive layer 150b and the electron injection layer 150c may be formed by spin coating the liquid material or coating the liquid material through an ink jet, nozzle or slit process and then drying the coated liquid material. In one exemplary embodiment, for example, the hole injection layer 150a, the emissive layer 150b and the electron injection layer 150c may be sequentially laminated on the first electrode 130 by repetitively performing the aforementioned procedure.

In one exemplary embodiment, for example, the liquid material of the hole injection layer 150a may include poly(3,4-ethylenedioxythiophene) poly(4-styrenesulfonate) (“PEDOT:PSS”), etc.

The liquid material of the hole transport layer may include Poly(3-hexylthiophene-2,5-diyl) (“P3HT”), triphenylamine tetramer (“TPTE”), N,N′-diphenyl-N,N′-bis(3-methylphenyl)-1,1′-biphenyl-4,4′-diaminodiphenylamine tetramer (“TPD”), etc.

The liquid material of the emissive layer 150b may include (cyano-1-phenyl)-1,1-biphenyl-4,4-diaminodiphenylamine tetramer (cyano-substituted “PPV”, “CN-PPV”), TPD, etc.

The liquid material of the electron injection layer 150c may include 2-(4-biphenylyl)-5-phenyl-1,3,4-oxadiazole (“PBD”), 3-(4-biphenylyl)-4-phenyl-5-(4-tert-butylphenyl)-1,2,4-triazole (“TAZ”), [6,6]-phenyl-C61-butyric acid methyl ester (“PCBM”), cesium carbonate (Cs₂CO₃), zinc oxide (“ZnO”), etc.

Although some materials have been disclosed as examples of the liquid material, the invention is not limited thereto.

If the liquid material is coated or applied on the first electrode 130, a height h1 at a central portion of the liquid material is higher than the height h2 at a peripheral portion of the liquid material. The vapor density of the solvent at the central portion of the liquid material is higher than that of the solvent at the peripheral portion of the liquid material (see FIG. 5D). However, since the drying speed of the solvent is in inverse proportion to the vapor density of the solvent, the solvent at the peripheral portion of the liquid material is removed faster than the solvent at the central portion of the liquid material during the drying process. Accordingly, the organic material at the central portion is moved to the peripheral portion, so that the height h2 at the peripheral portion becomes higher than the height h1 at the central portion (see FIG. 5E).

Referring to FIG. 5F, a second insulating material layer is formed on the first insulating layer 140 and the organic layer 150 and then patterned. The second insulating material layer is patterned so that opposing side portions of the second insulating layer 160 are protruded further outward than those of the first insulating layer 140, at the opening 140a.

The second insulating layer 160 may be formed of an organic or inorganic material, and may include the same material used for the first insulating layer 140. In an exemplary embodiment, a cross-sectional thickness of the second insulating layer 160 smaller than that of the first insulating layer 140. Where the second insulating layer 160 is thicker than the first insulating layer 140, electrical disconnection of a second electrode 170 may be caused by step coverage when the second electrode 170 is formed in a subsequent process.

Referring again to FIG. 2, the second insulating layer 160 has a width wider than that of the first insulating layer 140 at portions adjacent to openings 140a, so that opposing side portions of the second insulating layer 160 are positioned in the opening 140a. Both lower portions of second insulating layer 160 portions opposing an emission region, can be contacted with the organic layer 150 in the opening 140a at the emission region.

As another exemplary embodiment of a manufacturing method of an organic light emitting display, the second insulating layer 160 may be formed by coating a liquid material on the first insulating layer 140 as shown in FIG. 3B. In one exemplary embodiment, for example, the liquid material may be dropped on the first insulating layer 140 through an ink jet, nozzle or slit process and then dried, thereby forming the second insulating layer 160 having a curved surface.

Referring to FIG. 5G, the second electrode 170 is formed on the organic layer 150.

The second electrode 170 may be discretely disposed on each organic layer 150, or may be disposed as a common electrode on the substrate 100 including the organic layer 150 and the second insulating layer 160.

The second electrode 170 may be formed of metal material such as Al or Ag.

Where the second insulating layer 160 is omitted from the an organic light emitting display, the second electrode 170 is disposed as shown in FIG. 6. In a manufacturing method of an organic light emitting display, the second electrode 170 may be formed on the organic layer 150, such as in the state in which the organic layer 150 is formed as shown in FIG. 5C.

Since the height h2 at the peripheral portion of the organic layer 150 is higher than the height h1 at the central portion of the organic layer 150 in forming the organic layer 150 (see FIGS. 5D and 5E), the organic layer 150 at the peripheral portion can be contacted with the second electrode 170 (see portion X in FIG. 6). Where the hole injection layer 150a of the organic layer 150 having a relatively high conductivity is contacted with the second electrode 170, power consumption is increased by leakage current or an electrical short circuit, or a failure may occur in the organic light emitting display, due to the hole injection layer 150a of the organic layer 150 having a relatively high conductivity being contacted with the second electrode 170.

However, in one or more exemplary embodiment of the invention, contact between the organic layer 150 and the second electrode 170 is prevented in advance of forming the second electrode 170, by the second insulating layer 160, so that power consumption increased by leakage current, an electrical short circuit, or a failure in the organic light emitting display may be reduced or effectively prevented.

Where the height h2 at the peripheral portion of the organic layer 150 is higher than the height h1 at the central portion of the organic layer 150, a change in color may occur due to non-uniform thickness of the organic layer 150. However, in one or more exemplary embodiment of the invention, the peripheral portion of the organic layer 150, which is relatively thick, is overlapped with the second insulating layer 160, so that a change in color is not easily viewed.

According to one or more exemplary embodiment of the invention, the organic layer including a liquid material is disposed in the opening of the first insulating layer used as a pixel defining layer, and the second insulating layer is disposed on the first insulating layer to have a width larger than that of the first insulating layer. The electrical contact between the organic layer and the second electrode is reduced or effectively prevented by the second insulating layer having the side portions protruded further outward than the first insulating layer.

Exemplary embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular exemplary embodiment may be used singly or in combination with features, characteristics, and/or elements described in connection with other exemplary embodiments unless otherwise specifically indicated. Accordingly, it will be understood by those of skill in the art that various changes in form and details may be made without departing from the spirit and scope of the invention as set forth in the following claims

What is claimed is:

1. An organic light emitting display, comprising:
a substrate;
a first electrode on the substrate;
a first insulating layer on the first electrode, and an opening defined in the first insulating layer, wherein the first electrode is exposed through the opening;
a second insulating layer on the first insulating layer, wherein a width of the second insulating layer is larger than that of the first insulating layer;
an organic layer on the first electrode in the opening; and
a second electrode on the organic layer and the second insulating layer.

2. The organic light emitting display of claim 1, wherein a thickness of the organic layer at an edge portion of the opening is larger than that of the organic layer at a central portion of the opening.

3. The organic light emitting display of claim 2, wherein the organic layer contacts the second insulating layer at the edge portion of the opening.

4. The organic light emitting display of claim 1, wherein the organic layer comprises a hole injection layer, an emissive layer and an electron injection layer.

5. The organic light emitting display of claim 1, wherein a width of a lower portion of the second insulating layer is larger than that of an upper portion of the second insulating layer.

6. The organic light emitting display of claim 1, wherein the second insulating layer has a curved surface.

7. The organic light emitting display of claim 1, further comprising a device forming layer on the substrate.

8. The organic light emitting display of claim 7, wherein the device forming layer comprises:
a thin film transistor coupled to the first electrode; and
a third insulating layer between the thin film transistor and the first electrode.

9. A method of manufacturing an organic light emitting display, the method comprising:
forming a first electrode on a substrate;
forming a first insulating layer on the first electrode;
patterning the first insulating layer, thereby forming an opening in the first insulating layer exposing the first electrode in an emission region;
forming an organic layer on the first electrode in the opening;
forming a second insulating layer on the first insulating layer to have a width larger than that of the first insulating layer; and
forming a second electrode on the organic layer and the second insulating layer.

10. The method of claim 9, wherein the forming the organic layer comprises:
coating a liquid material on the first electrode in the opening; and
drying the coated liquid material.

11. The method of claim 10, wherein, in the drying the coated liquid material, a thickness of the organic layer at an edge portion of the opening is larger than that of the organic layer at a central portion of the opening.

12. The method of claim 11, wherein the organic layer contacts the second insulating layer at the edge portion of the opening.

13. The method of claim 9, wherein the forming the organic layer comprises:
forming a hole injection layer by coating a hole injection layer liquid material on the first electrode in the opening and drying the coated hole injection layer liquid material;
forming an emissive layer by coating an emissive layer liquid material on the hole injection layer, and drying the coated emissive layer liquid material; and
forming an electron injection layer by coating an electron injection layer liquid material on the emissive layer, and drying the coated electron injection layer liquid material.

14. The method of claim 9, wherein the forming the second insulating layer comprises:
forming a second insulating material layer on the first insulating layer and the organic layer; and
patterning the second insulating material layer.

15. The method of claim 14, wherein, in the patterning the second insulating material layer, a width of a lower portion of the second insulating layer is formed larger than that of an upper portion of the second insulating layer.

16. The method of claim 9, wherein the forming the second insulating layer comprises:
coating a second insulating layer liquid material on the first insulating layer; and
drying the coated second insulating layer liquid material.

17. The method of claim 9, further comprising:
forming a thin film transistor on the substrate;
forming a third insulating layer on the thin film transistor; and
forming, in the third insulating layer, a via hole through which the thin film transistor and the first electrode are coupled to each other.

18. The method of claim 11, wherein in the forming the second insulating layer, the second insulating layer overlaps the organic layer in the opening, at the edge portion of the opening.

19. The method of claim 11, wherein in the coating the liquid material on the first electrode in the opening, the thickness of the organic layer at the edge portion of the opening is smaller than that of the organic layer at the central portion of the opening.
